(19) United States
(12) Patent Application Publication
(10) Pub. No.: US 2012/0160546 A1
(43) Pub. Date: Jun. 28, 2012

(54) Heat radiation board formed using electro-deposition coating and method of manufacturing the same

(75) Inventors: Sanghyun Shin, Suwon-si (KR); Youngki Lee, Hwaseong-si (KR); Cheolho Heo, Busan-si (KR)

(73) Assignee: SAMSUNG ELECTRO-MECHANICS CO., LTD., Suwon (KR)

(21) Appl. No.: 13/067,052

(22) Filed: May 4, 2011

(30) Foreign Application Priority Data
Dec. 24, 2010 (KR) 10-2010-0134697

(51) Int. Cl. H05K 7/20; C25D 11/26; C25D 11/30; C25D 11/02; C25D 11/04

(52) U.S. Cl. 174/252; 205/171; 205/172

(57) ABSTRACT

Provided are a heat radiation board and a method of manufacturing the same, and more particularly, to a heat radiation board formed using electro-deposition coating, in which a circuit is formed by forming a first insulating layer through anodizing and forming a second insulating layer through electro-deposition coating, and a method of manufacturing the same.

The method of manufacturing the heat radiation board using electro-deposition coating includes preparing a metal core, forming a first insulating layer on the metal core by anodizing, forming a second insulating layer on the metal core, on which the first insulating layer is formed, by the electro-deposition coating, and forming a circuit layer.

Therefore, since the first insulating layer is formed by anodizing and the second insulating layer is formed by electro-deposition coating, thermal conductivity is increased and thus radiation effect is improved.

### CROSS-REFERENCE TO RELATED APPLICATIONS

Claim and incorporate by reference domestic priority application and foreign priority application as follows:

### “CROSS REFERENCE TO RELATED APPLICATION

This application claims the benefit under 35 U.S.C. Section 119 of Korean Patent Application Serial No. 10-2010-0134697, entitled filed Dec. 24, 2010, which is hereby incorporated by reference in its entirety into this application.”

### BACKGROUND OF THE INVENTION

1. Field of the Invention

The present invention relates to a heat radiation board and a method of manufacturing the same, and more particularly, to a heat radiation board formed using electro-deposition coating, in which a circuit is formed by forming a first insulating layer through anodizing and forming a second insulating layer through electro-deposition coating, and a method of manufacturing the same.

2. Description of the Related Art

A scale of a worldwide market of a light emitting diode (LED) is about 3.7 billion dollars, an application market of the LED is also actively increased due to development of a high brightness LED technique, and a utilization region of the LED is anticipated to be further expanded in the future.

In LEDs, a power LED, which is a high output LED of 1 W or more, consumes a relatively large amount of electric power and has a large amount of current sufficient to obtain high luminous efficiency, but a caloric value of an LED chip is still high. Accordingly, if a solution for radiating heat is not prepared, a temperature of the LED chip becomes too high, and thus, the chip itself or a packing resin may be deteriorated. When such a phenomenon occurs, an illuminance may decrease to lower luminous efficiency and a lifespan of the chip may be decreased.

Meanwhile, application fields of the LED are being expanded to illuminations as well as LCD TV backlights. The illuminations are generally classified into indoor illuminations and outdoor illuminations. In particular, the outdoor illuminations have a large voltage or current value and an LED packaging thereof is generally applied by arranging high electric power packaging of 1 W or more, unlike the indoor illuminations.

The LED emits light and heat while operating, about 20 to 30% of heat and about 70 to 80% of heat, unlike a general lamp. In particular, the heat generated while operating must be rapidly radiated to increase luminous efficiency. In order to effectively transfer the heat, a metal circuit board is generally used.

FIG. 1A shows a conventional process of manufacturing a printed circuit board (PCB), for example, a metal copper clad laminate (MCCL) PCB. In an MCCL method, one of typical methods of manufacturing metal circuit boards, since a thick insulating layer is adhered to a lower part of a conductive circuit to form an insulating layer through a pressing method, the board may have a low heat resistant property and may be delaminated.

FIG. 1B shows a conventional process of manufacturing an AMS board. An AMS method, another typical method of manufacturing a metal circuit board, includes plating a metal to a surface, to which an anode-oxidation film is to be formed, after forming a seed layer. Here, a method of forming the seed layer may be a wet method or a dry method. In particular, in the wet method, according to process environments, an error that the anode-oxidation film is etched may occur to decrease characteristics of products. That is, even when the AMS method is used, a plating process cannot be easily performed to the surface to which the anode-oxidation film is formed.

### SUMMARY OF THE INVENTION

The present invention has been invented in order to overcome the above-described problems and it is, therefore, an object of the present invention to provide a heat radiation board and a method of manufacturing the same, which includes forming a first insulating layer through anodizing and forming a second insulating layer through electro-deposition coating, increasing heat conductivity.

In accordance with one aspect of the present invention to achieve the object, there is provided a method of manufacturing a heat radiation board using electro-deposition coating, which includes preparing a metal core; forming a first insulating layer on the metal core by anodizing; forming a second insulating layer on the metal core, on which the first insulating layer is formed, by electro-deposition coating; and forming a circuit layer.

In addition, the method may further include forming a seed layer on the second insulating layer by a wet method or a dry method; and forming a plating layer on the seed layer.

The metal core may include any one metal material selected from aluminum, magnesium, and titanium.

In forming the first insulating layer on the metal core by anodizing, the first insulating layer may be formed on one surface or both surfaces of the metal core.

In accordance with another aspect of the present invention to achieve the object, there is provided a method of manufacturing a heat radiation board using electro-deposition coating, which includes preparing a metal core; forming a hole in the metal core; forming a first insulating layer on the metal core, in which the hole is formed, by anodizing; forming a second insulating layer on the metal core, on which the first insulating layer is formed, by electro-deposition coating; and forming a circuit layer.

In addition, the method may further include forming a seed layer on the second insulating layer by a wet method or a dry method; and forming a plating layer on the seed layer.

The metal core may include any one metal material selected from aluminum, magnesium and titanium.

In forming the first insulating layer on the metal core by anodizing, the first insulating layer may be formed on one surface or both surfaces of the metal core.

In accordance with still another aspect of the present invention to achieve the object, there is provided a method of manufacturing a heat radiation board using electro-deposition coating, which includes preparing a metal core; forming a first insulating layer on the metal core by anodizing; forming a hole in the metal core, on which the first insulating layer is formed; forming a second insulating layer on the metal core, in which the hole is formed, by electro-deposition coating; and forming a circuit layer.

In addition, the method may further include forming a seed layer on the second insulating layer by a wet method or a dry method; and forming a plating layer on the seed layer.

The metal core may include any one metal material selected from aluminum, magnesium and titanium.

In forming the first insulating layer on the metal core by anodizing, the first insulating layer may be formed on one surface or both surfaces of the metal core.

In accordance with yet another aspect of the present invention to achieve the object, there is provided a heat radiation board formed using electro-deposition coating, which includes a metal core; a first insulating layer formed on one surface or both surfaces of the metal core by anodizing; a second insulating layer formed on the metal core, on which the first insulating layer is formed, by electro-deposition coating; a seed layer formed on the second insulating layer by a wet method or a dry method; a plating layer formed on the seed layer; and a circuit layer formed using the plating layer.

In accordance with yet still another aspect of the present invention to achieve the object, there is provided a heat radiation board formed using electro-deposition coating, which includes a metal core, in which a hole is formed; a first insulating layer formed on one surface or both surfaces of the metal core by anodizing; a second insulating layer formed on the metal core, on which the first insulating layer is formed, by electro-deposition coating; a seed layer formed on the second insulating layer by a wet method or a dry method; a plating layer formed on the seed layer; and a circuit layer formed using the plating layer.

In accordance with further still another aspect of the present invention to achieve the object, there is provided a heat radiation board formed using electro-deposition coating, which includes a metal core; a first insulating layer formed on one surface or both surfaces of the metal core by anodizing; a hole formed in the metal core, on which the first insulating layer is formed; a second insulating layer formed on the metal core, on which the hole is formed, by electro-deposition coating; a seed layer formed on the second insulating layer by a wet method or a dry method; a plating layer formed on the seed layer; and a circuit layer formed using the plating layer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a flowchart showing a conventional method of manufacturing a PCB;

FIG. 1B is a flowchart showing a conventional method of manufacturing an AMS board.

FIG. 2 is a flowchart showing a method of manufacturing a heat radiation board formed using electro-deposition coating according to a first embodiment;

FIGS. 3A and 4A are cross-sectional views of the heat radiation board electro-deposition coated according to the first embodiment of the present invention;

FIGS. 3B and 4B are cross-sectional views of the heat radiation board, on which a circuit is formed, according to the first embodiment of the present invention;

FIG. 5 is a flowchart showing a method of manufacturing a heat radiation board formed using electro-deposition coating according to a second embodiment;

FIG. 6 is a cross-sectional view showing the method of manufacturing the heat radiation board formed using electro-deposition coating according to the second embodiment;

FIG. 7 is a flowchart showing a method of manufacturing a heat radiation board formed using electro-deposition coating according to a third embodiment;

FIG. 8 is a cross-sectional view showing the method manufacturing the heat radiation board formed using electro-deposition coating according to the third embodiment;

FIG. 9 is a cross-sectional view showing the heat radiation board formed by the method of manufacturing the heat radiation board formed using electro-deposition coating according to the second embodiment; and

FIG. 10 is a cross-sectional view showing the heat radiation board formed by the method of manufacturing the heat radiation board formed using electro-deposition coating according to the third embodiment.

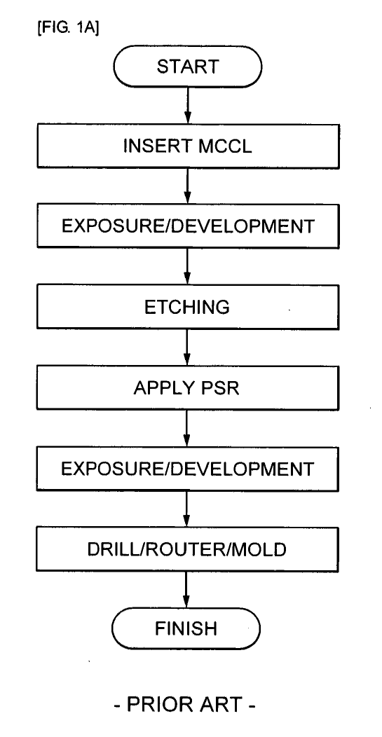

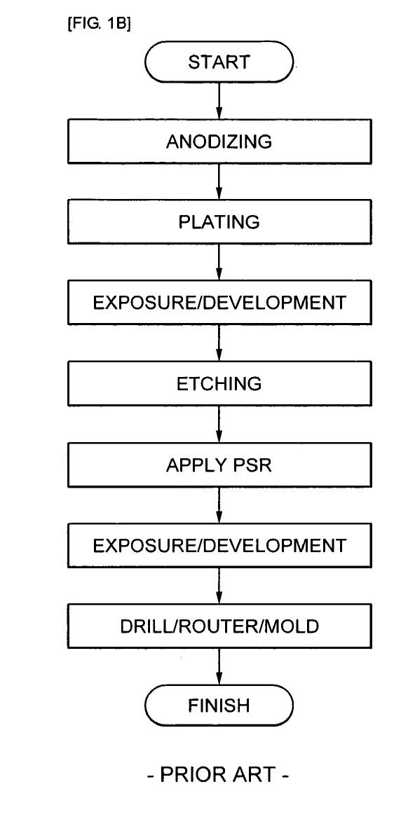

### DETAILED DESCRIPTION OF THE PREFERABLE EMBODIMENTS

Hereinafter, exemplary embodiments of the present invention will be described in detail with reference to the accompanying drawings. The following embodiments are provided as examples to fully convey the spirit of the invention to those skilled in the art. The terms used in the specification and claims are defined in consideration of functions of the present invention and may be changed according to users or operator's intentions or customs. Thus, the terms shall be defined based on the contents described throughout the specification.

Therefore, the present invention should not be construed as limited to the embodiments set forth herein and may be embodied in different forms. And, the size and the thickness of an apparatus may be overdrawn in the drawings for the convenience of explanation. The same components are represented by the same reference numerals hereinafter.

The present invention relates to a heat radiation board formed using electro-deposition coating, in which a circuit is formed by forming a first insulating layer through anodizing and forming a second insulating layer through electro-deposition coating, and a method of manufacturing the same.

### First Embodiment

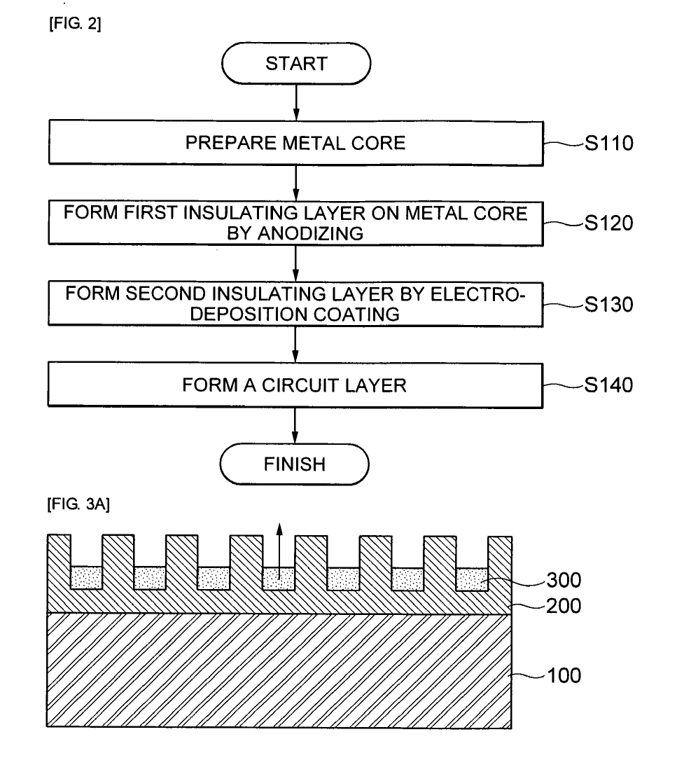

FIG. 2 is a flowchart showing a method of manufacturing a heat radiation board formed using electro-deposition coating according to a first embodiment. The method of manufacturing the heat radiation board formed using electro-deposition coating will be described with reference to FIG. 2.

A metal core is prepared (S110). Here, the metal core may have various shapes such as a plate shape, a circular shape, a rectangular shape, a polygonal shape, etc., and may be formed of any one metal selected from aluminum, magnesium and titanium. However, the metal is not limited thereto but may constitute the metal core as long as the metal can form an insulating layer.

A first insulating layer is formed on the metal core by anodizing (S120). The first insulating layer may be formed on one surface or both surfaces of the metal core. In the anodizing, the metal core acts as an anode in a specific solution such as sulfuric acid, etc., to accelerate an oxidation reaction on a surface of the metal core so that an oxidation layer is artificially formed to a uniform thickness, forming the insulating layer.

A second insulating layer is formed on the metal core, on which the first insulating layer is formed, through electro-deposition coating (S130), and a circuit layer is formed (S140) to manufacture the heat radiation board. Here, the circuit layer may be formed through processes such as exposure, development, etching, and so on. Since the processes of forming the circuit layer, which can be applied to the embodiment, are performed through the conventional processes for forming the circuit layer, detailed description will be omitted.

In addition, the electro-deposition coating is a coating method of depositing an object to be coated in an electro-deposition aqueous paint solution using the object to be coated as an anode or a cathode, and applying direct current between the object to be coated and an opposite electrode to electrically deposit a coating film on the object to be coated, which may be referred to as electro-coating, electro-phoretic coating, electrophoretic-deposition coating, etc.

That is, in the electro-deposition coating, when direct current is applied between the object to be coated, which is deposited as an anode or a cathode in the electro-deposition coating solution, and the opposite electrode, electrolysis, electro-deposition and electroosmosis are simultaneously performed to electrically deposit a paint on a surface of the object to be coated. Since an electro-deposition coating process, which can be applied to the embodiment, can be performed using a conventional electro-deposition process, detailed description of the electro-deposition coating process and method will be omitted.

In addition, similar to the electro-deposition coating, an electrostatic coating is a method of spraying a paint to perform the coating, rather than dipping a substrate in a solution. In the present invention, the electro-deposition coating may be the electrostatic coating. Even when only the electro-deposition coating is described below, the electrostatic coating may be also similarly applied.

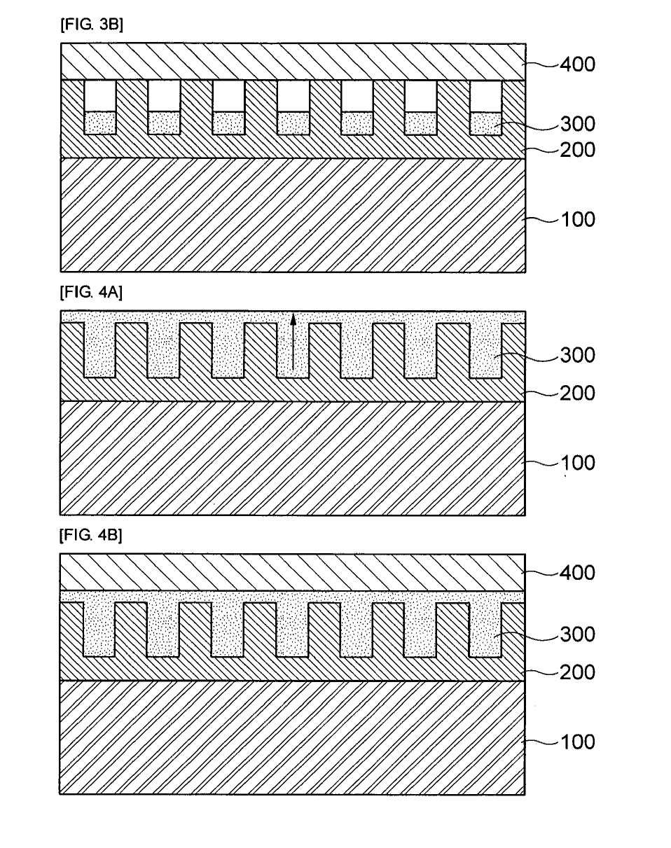

FIGS. 3A and 4A are cross-sectional views of the heat radiation board electro-deposition coated according to the first embodiment of the present invention. As shown, when a first insulating layer 200 is formed on a metal core 100 by anodizing, a plurality of pores are formed in a surface of the first insulating layer 200. Here, when the electro-deposition coating is performed, the pores may be partially filled as shown in FIG. 3A or may be completely filled. Or, as shown in FIG. 4A, insides of the pores may be filled and additionally a coating may be formed on the surface of the anodized metal core 100.

FIGS. 3B and 4B are cross-sectional views of the heat radiation board, on which a circuit is formed, according to the first embodiment of the present invention. As shown in FIG. 3B, after performing the electro-deposition coating similar to FIG. 3A to partially fill the pores, a circuit layer 400 may be formed to manufacturing the heat radiation board. In addition, as shown in FIG. 4B, after performing the electro-deposition coating similar to FIG. 4a to fill the insides of the pores and additionally coating the surface of the anodized metal core 110, the circuit layer 400 may be formed of manufacturing the heat radiation board.

According to the first embodiment of the present invention, the heat radiation board may be manufactured without forming a separate via-hole. That is, as the insulating layer is etched to form an interconnection, which can be electrically connected, on one surface or both surfaces of the metal core, the heat radiation board can be used as an independent board, without forming the via-hole for separate electrical connection in an upper surface of the insulating layer of the metal core.

While not shown, the method of the first embodiment may further include forming a seed layer on the second insulating layer using a wet method or a dry method, and forming a plating layer on the seed layer. Since processes of forming the seed layer and the plating layer, which can be applied to the first embodiment, may be performed using conventional processes of forming the seed layer and the plating layer, detailed description of the process and method thereof will be omitted.

Meanwhile, the present invention provides the heat radiation board manufactured according to the first embodiment. That is, the heat radiation board in accordance with the present invention includes the metal core 100, the first insulating layer 200 formed on one surface or both surfaces of the metal core 100 by anodizing, the second insulating layer 300 formed on the metal core 100, on which the insulating layer 200 is formed, through electro-deposition coating, the seed layer (not shown) formed on the second insulating layer 300 through the wet method or the dry method, the plating layer (not shown) formed on the seed layer, and the circuit layer 400 formed using the plating layer.

### Second Embodiment

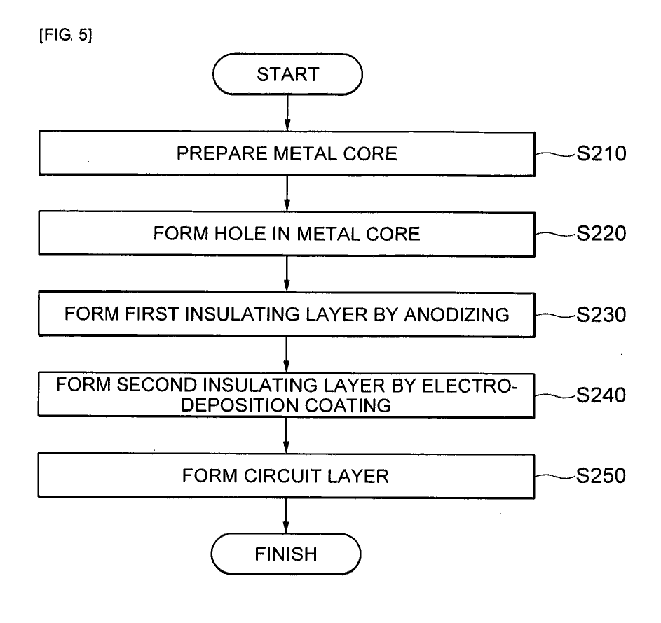

FIG. 5 is a flowchart showing a method of manufacturing a heat radiation board formed using electro-deposition coating according to a second embodiment. The method of manufacturing the heat radiation board formed using electro-deposition coating will be described with reference to FIG. 5.

A metal core is prepared (S210). As described above, the metal core may have various shapes such as a plate shape, a circular shape, a rectangular shape, a polygonal shape, etc., and may be formed of any one metal selected from aluminum, magnesium and titanium. However, the metal is not limited thereto but may constitute the metal core as long as the metal can form an insulating layer.

A hole is formed in the metal core (S220). The hole may be referred to as a general hole including a via-hole or a connection hole for electrical connection. While the hole may be formed using a general mechanical drill or a chemical etching method, the hole of the present invention is not limited thereto but may be formed through various methods.

A first insulating layer is formed on the metal core, in which the hole is formed, by anodizing (S230). As described above, the first insulating layer may be formed on one surface or both surfaces of the metal core. The process of forming the first insulating layer by anodizing is the same as described above.

A second insulating layer is formed on the metal core, to which the first insulating layer is formed, through electro-deposition coating (S240), and a circuit layer is formed (S250) to manufacture the heat radiation board. Here, since the circuit layer may be performed using conventional processes of forming the circuit layer such as exposure, development, etching, etc. as described above, detailed description thereof will be omitted. The electro-deposition coating is also the same as described above.

While not shown, the method of the second embodiment may further include forming a seed layer on the second insulating layer using a wet method or a dry method, and forming a plating layer on the seed layer. Since processes of forming the seed layer and the plating layer, which can be applied to the second embodiment, may be performed using conventional processes of forming the seed layer and the plating layer, detailed description of the process and method thereof will be omitted.

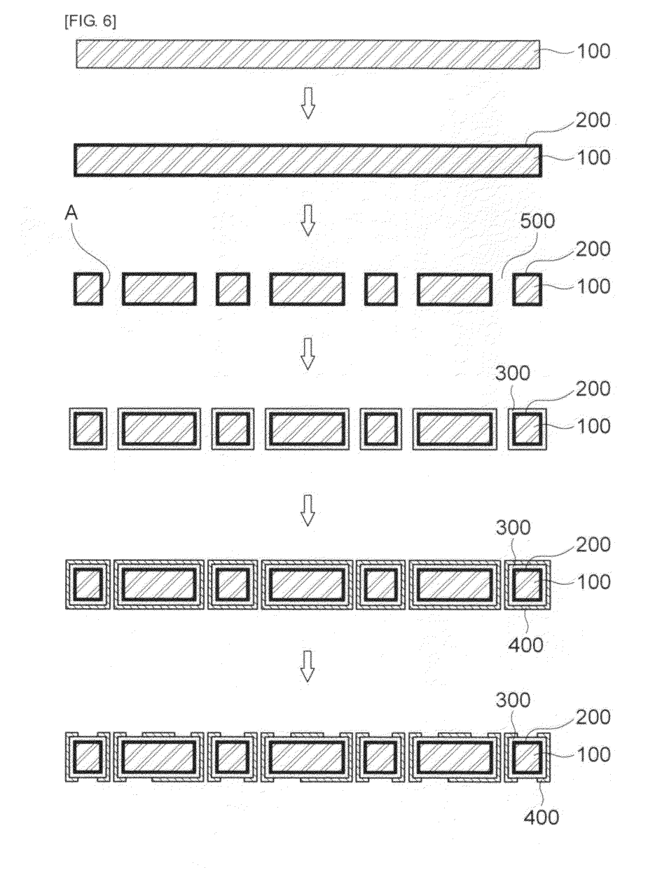

FIG. 6 is a cross-sectional view of the method of manufacturing the high radiation board formed using electro-deposition coating according to the second embodiment. The method according to the second embodiment will be described again in comparison with a method of manufacturing a high radiation substrate using electro-deposition coating according to a third embodiment, which will be described later.

Meanwhile, the present invention provides the heat radiation board manufactured according to the second embodiment. That is, the heat radiation board in accordance with the present invention includes the metal core 100 in which the hole is formed, the first insulating layer 200 formed on one surface or both surfaces of the metal core 100 by anodizing, the second insulating layer 300 formed on the metal core 100, on which the first insulating layer 200 is formed, through electro-deposition coating, the seed layer (not shown) formed on the second insulating layer by the wet method or the dry method, the plating layer (not shown) formed of the seed layer, and the circuit layer 400 formed using the plating layer.

### Third Embodiment

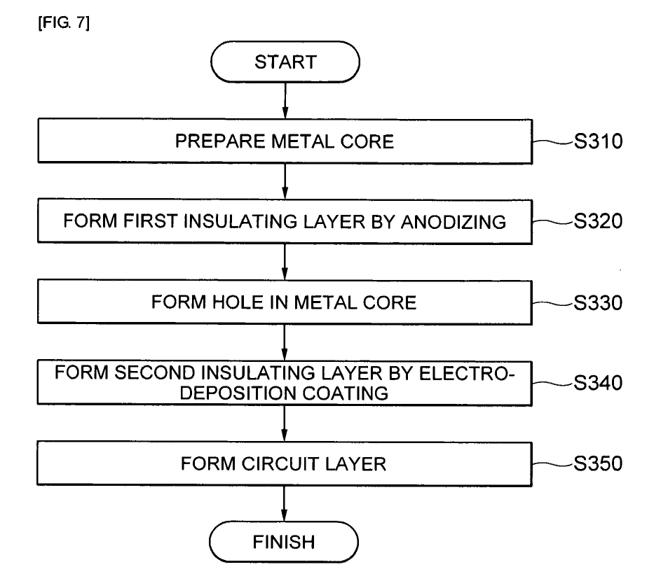

FIG. 7 is a flowchart showing a method of manufacturing a heat radiation board formed using electro-deposition coating according to a third embodiment. The method of manufacturing the heat radiation board formed using electro-deposition coating will be described with reference to FIG. 7.

A metal core is provided (S310). As described above, the metal core may have various shapes such as a plate shape, a circular shape, a rectangular shape, a polygonal shape, etc., and may be formed of any one metal selected from aluminum, magnesium and titanium. However, the metal is not limited thereto but may constitute the metal core as long as the metal can form an insulating layer.

A first insulating layer is formed on the metal core by anodizing (S320). As described above, the first insulating layer may be formed on one surface or both surfaces of the metal core. The process of forming the first insulating layer by anodizing is the same as described above.

A hole is formed in the metal core (S330). The hole may be referred to as a general hole including a via-hole or a connection hole for electrical connection. In addition, the hole may be formed to pass through the metal core. While the hole may be formed using a general mechanical drill or a chemical etching method, the hole of the present invention is not limited thereto but may be formed through various methods.

A second insulating layer is formed on the metal core, in which the hole is formed, through electro-deposition coating (S340), and a circuit layer is formed (S350) to manufacture the heat radiation board. Here, since the circuit layer may be performed using conventional processes of forming the circuit layer such as exposure, development, etching, etc. as described above, detailed description thereof will be omitted. The electro-deposition coating is also the same as described above.

While not shown, the method of the third embodiment may further include forming a seed layer on the second insulating layer using a wet method or a dry method, and forming a plating layer on the seed layer. Since processes of forming the seed layer and the plating layer, which can be applied to the third embodiment, may be performed using conventional processes of forming the seed layer and the plating layer, detailed description of the process and method thereof will be omitted.

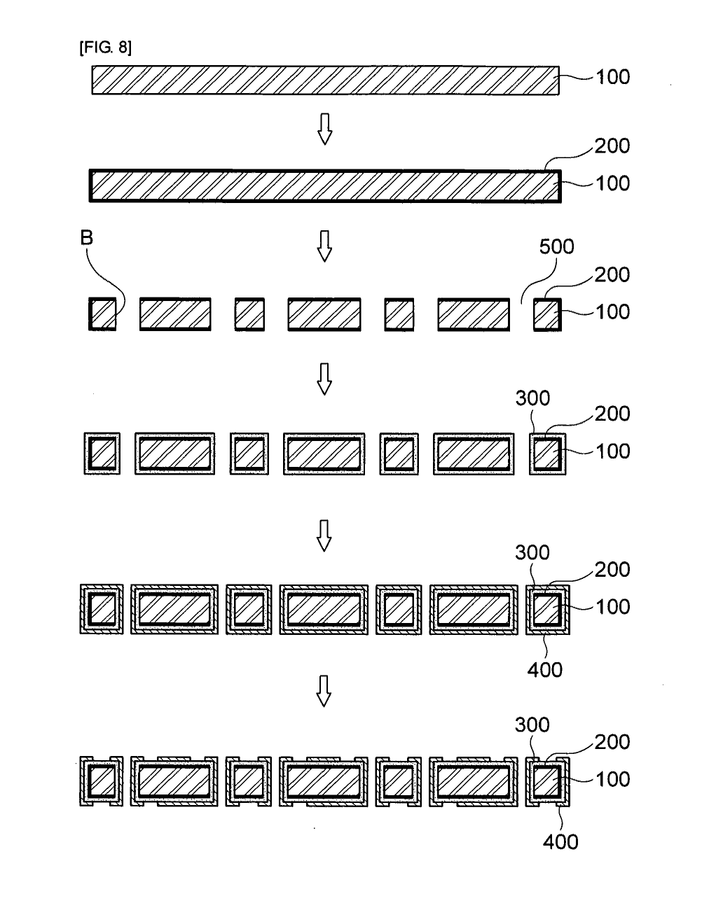

FIG. 8 is a cross-sectional view showing the method of manufacturing the heat radiation substrate using electro-deposition coating according to the third embodiment. The method of manufacturing the heat radiation board formed using electro-deposition coating according to the third embodiment of the present invention will be described in detain with reference to FIG. 8.

A metal core 100 is prepared. In FIG. 8, the metal core 100 having a plate shape is exemplarily described. A first insulating layer 200 is formed on the metal core 100 by anodizing. While the first insulating layer 200 may be formed on one surface or both surfaces of the metal core, the first insulating layer 200 formed on the both surfaces are exemplarily described in FIG. 8.

Holes 500 are formed in the metal core, on which the first insulating layer is formed. Accordingly, in FIG. 8, the holes 500 are formed to expose portions P of the metal core 100. However, in the method of manufacturing the heat radiation board formed using electro-deposition coating according to the second embodiment, as shown in FIG. 6, after forming the holes 500 in the metal core 100, the first insulating layer 200 is formed by anodizing, and thus, the first insulating layer 200 is formed even at portions A of the metal core 100, through which the holes 500 passes, without exposing the metal core 100.

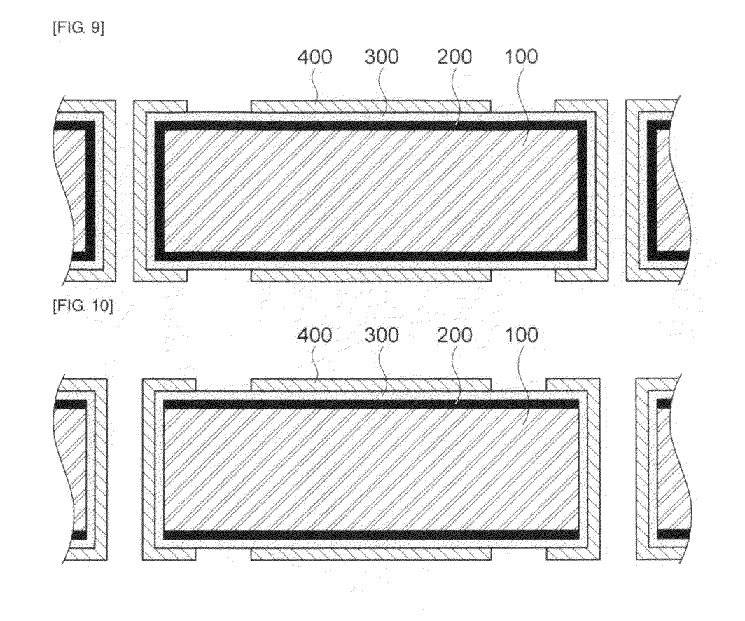

FIG. 9 is a cross-sectional view showing the heat radiation board formed by the method of manufacturing the heat radiation board formed using electro-deposition coating according to the second embodiment, and FIG. 10 is a cross-sectional view showing the heat radiation board formed by the method of manufacturing the heat radiation board formed using electro-deposition coating according to the third embodiment. Comparing FIGS. 9 and 10, a difference between the second and third embodiments will be more apparent.

The second insulating layer 300 is formed on the metal core 100, in which the holes 500 are formed, through electro-deposition coating. The seed layer and the plating layer formed on the second insulating layer 300 are not only disposed at upper and lower surfaces of the metal core 100 to form circuit patterns but also disposed in the holes to function to electrically connect the circuit patterns disposed at the upper and lower surfaces. When the plating layer is formed, the circuit layer 400 is formed through the conventional circuit forming processes such as exposure, development, etching, etc.

Meanwhile, the present invention provides the heat radiation board manufactured according to the third embodiment. That is, the heat radiation board in accordance with the present invention includes the metal core 100, the first insulating layer 200 formed on one surface or both surfaces of the metal core 100 by anodizing, the holes 500 formed in the metal core 100, on which the first insulating layer 200 is formed, the second insulating layer 300 formed on the metal core 100, in which the holes 500 are formed, through electro-deposition coating, the seed layer (not shown) formed on the second insulating layer 300 by the wet method or the dry method, the plating layer (not shown) formed on the seed layer, and the circuit layer 400 formed using the plating layer.

As can be seen from the foregoing, effects of the heat radiation board formed using electro-deposition coating and the method of manufacturing the same in accordance with the present invention are as follows.

First, as the first insulating layer is formed by anodizing and the second insulating layer is formed by electro-deposition coating, heat conductivity is increased and thus radiation effect is also improved.

Second, as the first insulating layer is formed by anodizing and the second insulating layer is formed by electro-deposition coating, manufacturing cost can be reduced.

Third, since heat conductivity is good, when the board is used for a high output LED, luminous efficiency can be increased and lifespan of the LED chip can be increased.

Fourth, since the method can be applied to a method of manufacturing a printed circuit board, a utilization range thereof can be increased.

As described above, although the preferable embodiments of the present invention have been shown and described, it will be appreciated by those skilled in the art that substitutions, modifications and variations may be made in these embodiments without departing from the principles and spirit of the general inventive concept, the scope of which is defined in the appended claims and their equivalents.

What is claimed is:

1. A method of manufacturing a heat radiation board using electro-deposition coating, which comprises:
preparing a metal core;
forming a first insulating layer on the metal core by anodizing;
forming a second insulating layer on the metal core, on which the first insulating layer is formed, by electro-deposition coating; and
forming a circuit layer.

2. The method according to claim 1, further comprising:
forming a seed layer on the second insulating layer by a wet method or a dry method; and
forming a plating layer on the seed layer.

3. The method according to claim 1, wherein the metal core comprises any one metal material selected from aluminum, magnesium, and titanium.

4. The method according to claim 1, wherein, in forming the first insulating layer on the metal core by anodizing, the first insulating layer is formed on one surface or both surfaces of the metal core.

5. A method of manufacturing a heat radiation board using electro-deposition coating, which comprises:
preparing a metal core;
forming a hole in the metal core;
forming a first insulating layer on the metal core, in which the hole is formed, by anodizing;
forming a second insulating layer on the metal core, on which the first insulating layer is formed, by electro-deposition coating; and
forming a circuit layer.

6. The method according to claim 5, further comprising:
forming a seed layer on the second insulating layer by a wet method or a dry method; and
forming a plating layer on the seed layer.

7. The method according to claim 5, wherein the metal core comprises any one metal material selected from aluminum, magnesium and titanium.

8. The method according to claim 5, wherein, in forming the first insulating layer on the metal core by anodizing, the first insulating layer is formed on one surface or both surfaces of the metal core.

9. A method of manufacturing a heat radiation board using electro-deposition coating, which comprises:
preparing a metal core;
forming a first insulating layer on the metal core by anodizing;
forming a hole in the metal core, on which the first insulating layer is formed;
forming a second insulating layer on the metal core, in which the hole is formed, by electro-deposition coating; and
forming a circuit layer.

10. The method according to claim 9, further comprising:
forming a seed layer on the second insulating layer by a wet method or a dry method; and
forming a plating layer on the seed layer.

11. The method according to claim 9, wherein the metal core comprises any one metal material selected from aluminum, magnesium and titanium.

12. The method according to claim 9, wherein, in forming the first insulating layer on the metal core by anodizing, the first insulating layer is formed on one surface or both surfaces of the metal core.

13. A heat radiation board formed using electro-deposition coating, which comprises:
a metal core;
a first insulating layer formed on one surface or both surfaces of the metal core by anodizing;
a second insulating layer formed on the metal core, on which the first insulating layer is formed, by electro-deposition coating;
a seed layer formed on the second insulating layer by a wet method or a dry method;
a plating layer formed on the seed layer; and
a circuit layer formed using the plating layer.

14. A heat radiation board formed using electro-deposition coating, which comprises:
a metal core, in which a hole is formed;
a first insulating layer formed on one surface or both surfaces of the metal core by anodizing;
a second insulating layer formed on the metal core, on which the first insulating layer is formed, by electro-deposition coating;
a seed layer formed on the second insulating layer by a wet method or a dry method;
a plating layer formed on the seed layer; and
a circuit layer formed using the plating layer.

15. A heat radiation board formed using electro-deposition coating, which comprises:
a metal core;
a first insulating layer formed on one surface or both surfaces of the metal core by anodizing;
a hole formed in the metal core, on which the first insulating layer is formed;
a second insulating layer formed on the metal core, on which the hole is formed, by electro-deposition coating;
a seed layer formed on the second insulating layer by a wet method or a dry method;
a plating layer formed on the seed layer; and
a circuit layer formed using the plating layer.
